(19) United States
(12) Patent Application Publication
(10) Pub. No.: US 2026/0121652 A1
(43) Pub. Date: Apr. 30, 2026

(54) METASTABILITY DETECTION AND CORRECTION IN ANALOG-TO-DIGITAL SIGNAL CONVERTERS

(71) Applicant: TEXAS INSTRUMENTS INCORPORATED, Dallas, TX (US)

(72) Inventors: Aniruddha Periyapatna Nagendra, Bangalore (IN); Ashlesha Yerramsetty, Hyderabad (IN); Atul Lele, Bangalore (IN); Meghna Agrawal, Bangalore (IN); Venkatesh Kadlimatti, Hubli (IN); Dhivya Ravichandran, Karaikal (IN); Ankitha M, Mangalore (IN)

(21) Appl. No.: 18/931,862

(22) Filed: Oct. 30, 2024

(51) Int. Cl. H03M 1/10

(52) U.S. Cl. CPC H03M 1/1014

(57) ABSTRACT

Embodiments disclosed herein relate to digital signal processing, and more particularly, to detecting metastability to reduce noise and improve performance of an analog-to-digital converter (ADC). In an example, an ADC is provided that includes comparator circuitry, synchronization circuitry, digital output circuitry, and stability checking circuitry. The comparator circuitry performs a comparison of an analog input signal to an analog feedback signal and outputs a result of the comparison. The synchronization circuitry samples the result of the comparison at different times, resulting in first and second sampled values. The digital output circuitry generates a digital output signal based on the first sampled value and outputs the digital output signal. The stability checking circuitry determines whether a metastability condition occurred with respect to the analog-to-digital converter based on the first and second sampled values and outputs an indication of whether the metastability condition occurred.

### TECHNICAL FIELD

This relates generally to analog-to-digital signal processing devices and systems, and more particularly to metastability detection and mitigation.

### BACKGROUND

In electronic systems, digital signal processing components (e.g., an analog-to-digital converter (ADC)) sample and convert analog signals to digital signals for use by various components of the electronic systems. To operate the digital signal processing components, an electronic system supplies the components with a supply power and with a clock signal. The ADC receives analog input signals, generate voltages for comparison purposes with the analog signals, and convert the analog input signals to digital output signals based on the comparisons. For example, an analog input signal may be converted to a one (or zero) depending on whether it is greater than (or less than) a comparison voltage.

Some analog signals fail to resolve correctly due to a condition referred to as metastability. Metastability is a condition whereby an ADC's comparator fails to make a definitive decision within a required timeframe. This may occur when an analog input signal is very close to a comparator's threshold, causing the comparator's output to be in an indeterminate state for a brief period of time. Furthermore, metastability can produce sparkle codes such as deviations from expected output signals not attributable to the effective Gaussian noise of the ADC.

Existing solutions attempt to resolve issues caused by metastable values encountered during digital signal processing. One example existing solution employs multiple redundant components in an ADC structure, such as multiple DACs or multiple comparators, that add redundancy to ensure capture of resolved, or stable, values during conversion processes. However, this solution increases design area requirements and cost based on using duplicate components.

Another existing solution obtains and converts multiple redundant samples of the analog input signals, determines a standard deviation of multiple converted digital output signals, and determines an average of the multiple digital output signals to dampen the impact of metastability. However, this solution decreases ADC throughput and increases the time required to convert the analog input signals to digital.

### SUMMARY

Various embodiments disclosed herein relate to the enhanced detection and reduction of metastability conditions in an analog-to-digital converter (ADC). In various embodiments, an ADC is provided that is capable of detecting metastability in a unique manner that allows the metastability condition to be corrected sooner than otherwise. The ADC may then be controlled to decrease the rate of metastability in the future.

In an example embodiment, an ADC includes comparator circuitry that may enter an undesirable metastability state. The ADC also includes synchronization circuitry, digital output circuitry, and stability checking circuitry. The stability checking circuitry is capable of determining the metastability condition of the comparator circuitry. One or both of the comparator circuitry and the synchronization circuitry may be controlled by the ADC either directly or indirectly to reduce or otherwise mitigate the occurrence of the metastability condition. In a hardware approach, other circuitry within the ADC may control trim levels to mitigate the metastability. In a software approach, the ADC may interrupt software on one or more processing cores in response to the occurrence of metastability. The software may then adjust the trim levels or other parameters to control the metastability.

In operation, digital-to-analog circuitry of the ADC converts a digital feedback signal (produced by the digital output circuitry) to an analog feedback signal. The comparator circuitry performs a comparison of an analog input signal to the analog feedback signal and outputs results of the comparison to the synchronization circuitry. The comparator circuitry performs the comparison based on the trim levels and/or other configurable parameters that may influence metastability.

The synchronization circuitry samples the results of the comparison at different times to produce first and second sampled values. The digital output circuitry generates and outputs the digital feedback signal and a digital output signal based on the result of the comparison. The stability checking circuitry detects or otherwise determines the occurrence of the metastability condition based on the first and second sampled values. The metastability condition (or the fact of its occurrence) may then be used moving-forward to govern one or more of how the comparison circuitry performs the signal comparison, how the synchronization circuitry samples the results of comparison.

This Summary is provided to introduce a selection of concepts in a simplified form that are further described below in the Detailed Description. It may be understood that this Summary is not intended to identify key features or essential features of the claimed subject matter, nor is it intended to be used to limit the scope of the claimed subject matter.

### BRIEF DESCRIPTION OF THE DRAWINGS

FIG. 1 illustrates an example system in an implementation.

FIG. 2 illustrates an example analog-to-digital converter in an implementation.

FIG. 3A illustrates an example method in an implementation.

FIG. 3B illustrates an example method in an implementation.

FIG. 4 illustrates an example analog-to-digital converter in an implementation.

FIG. 5 illustrates an example timing diagram corresponding to elements of an analog-to-digital converter in an implementation.

The drawings are not necessarily drawn to scale. In the drawings, like reference numerals designate corresponding parts throughout the several views. In some embodiments, components or operations may be separated into different blocks or may be combined into a single block.

### DETAILED DESCRIPTION

Disclosed herein are enhanced components, techniques, and systems related to analog-to-digital signal conversion, and in particular, to the detection and reduction of metastability conditions in analog-to-digital signal converter devices. Embodiments of the present disclosure are described in specific contexts, such as in analog-to-digital signal conversion and digital-to-analog signal conversion, which may be performed using successive approximation register (SAR) analog-to-digital converters (ADCs). Some embodiments may be used in other applications, such as in analog sampling and signal conversion, in sampling clocked analog outputs (e.g., clocked comparator outputs, operational amplifiers), and/or in other applications using different types of converters and components thereof.

In digital signal processing systems, ADCs sample analog input signals and convert the analog input signals to digital output signals for use by downstream components and systems. An exemplary ADC disclosed herein includes various components to not only perform the signal conversion but also to verify the accuracy of the conversion, such as components to detect and reduce metastability, and the effects thereof, during conversion of the analog input signals to the digital output signals.

In an example embodiment, an analog logic subsystem of the ADC includes digital-to-analog converter (DAC) circuitry and comparator circuitry that cooperatively function to process analog input signals and output a result to a digital logic subsystem. The digital logic subsystem, includes synchronization circuitry, digital output circuitry, and stability checking circuitry, processes the output from the analog logic subsystem to produce digital signals that are a digital representation of the analog input signals.

More specifically, the analog logic subsystem is coupled with the digital logic subsystem via an output of the comparator circuitry that feeds the inputs of the synchronization circuitry, as well as an output of the digital output circuitry that feeds an input of the comparator circuitry. The DAC circuitry converts a digital feedback signal (produced by the digital output circuitry) to an analog feedback signal. The comparator circuitry performs a comparison of an analog input signal to the analog feedback signal and outputs a result of the comparison to the synchronization circuitry. The synchronization circuitry samples the result at different times to produce first and second sampled values.

The first sampled value is provided as input to the digital output circuitry and to the stability checking circuitry. The digital output circuitry generates the digital feedback signal based on the first sampled value. The digital output circuitry then outputs the digital feedback signal to the DAC circuitry as discussed above.

The second sampled value is also provided as input to the stability checking circuitry. Thus, the stability checking circuitry receives both the first sampled value and the second sampled value as input. The stability checking circuitry processes the sampled values to determine or otherwise detect a metastability condition associated with the analog logic subsystem in general, and the comparator in particular.

Assuming the metastability state for exemplary purposes, one or more elements of the ADC may be controlled to reduce metastability including the comparator circuitry and the synchronization circuitry. In addition, the control may be provided directly and/or indirectly. For example, when a metastability state is detected, the stability checking circuitry may output an indication of the state to software executing on a processing core in the overall system in which the ADC is deployed. The software can determine to adjust operating parameters of the ADC to bring the system out of the metastability state. Alternatively—or in addition—the output of the stability checking circuitry may be used by other components of the ADC itself to directly adjust operating parameters of the ADC to mitigate the occurrence of metastability.

Even more specifically, the timing at which the comparator circuitry outputs the result of its comparison of the analog input signal and the analog feedback signal, and the timing at which the synchronization circuitry samples the comparison result, are based on various clock signals fed to respective components of the ADC. For example, the comparator circuitry operates in accordance with a first clock signal, while the synchronization circuitry operates in accordance with second and third clock signals delayed relative to the first clock signal to perform respective operations after the comparator circuitry. In various examples, the synchronization circuitry includes two synchronizers each configured to sample the result output by the comparator circuitry. A first synchronizer is fed the result and performs sampling operations based on the second clock signal. A second synchronizer is also fed the result and performs sampling operations based on the third clock signal. The third clock signal is delayed further than the second clock signal relative to the first clock signal, and thus, the second synchronizer samples the result to produce the second sampled value at a later time than the first synchronizer.

Problematically, when the duration between performance of the comparison by the comparator circuitry and the sampling by the synchronization circuitry is small (e.g., 1-2 ns), the result signal being passed from the comparator circuitry to the digital logic subsystem may be metastable as the comparator circuitry might not have had enough time to resolve the value of the result signal to a stable binary value (0, 1). When metastable values are used to generate the digital output signal by the digital output circuitry, noise is introduced in the digital output signals that is not attributable to the effective Gaussian noise of the ADC as metastable values cause inaccuracies in the digital output signals.

As disclosed herein, the stability checking circuitry detects metastability of the comparator circuitry output earlier than otherwise because the synchronizer circuitry captures sampled values from the comparator circuitry output and provides the sampled values to the stability checking circuitry prior to the generation of the feedback signal and the digital output signal. The timing and sequence of operations allows the ADC to take corrective and/or preventative action before the digital output signal is fully complete and/or output for downstream use. For example, corrective actions may include directing the digital output circuitry to use different (e.g., approximate) values to generate the digital output signals, directing the comparator circuitry to use updated parameters (e.g., trim settings) for subsequent comparison operations, and the like. Preventative actions may include terminating conversion operations early, discarding digital output bits generated up to or after a certain time, and the like.

Advantageously, the ADC is able to generate and operate stable digital output signals despite potential metastable signals output by components of the ADC during the sampling and conversion process, which in turn reduces noise in the digital output signals and improves performance of the ADC.

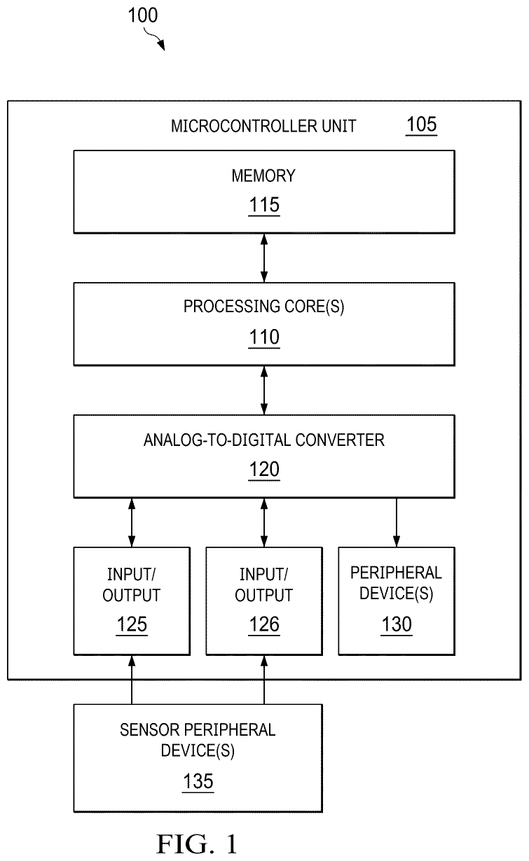

Turning now to the Figures, FIG. 1 illustrates an example system configurable to convert analog input signals to digital output signals in an implementation. FIG. 1 shows system 100, which includes microcontroller unit (MCU) 105 and sensor peripheral devices 135. MCU 105 may include one or more processing cores 110, memory 115, analog-to-digital converter (ADC) 120, input/output (I/O) device 125, I/O device 126, and peripheral devices 130.

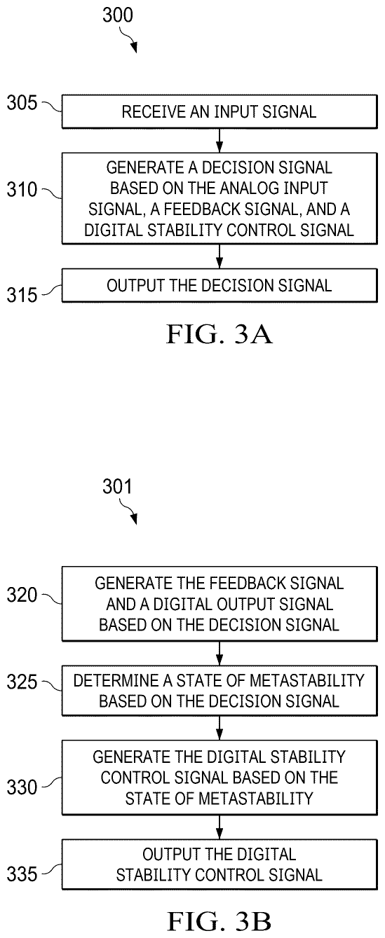

In various examples, system 100 is representative of a processing system capable of converting analog input signals to digital output signals via ADC 120 and providing the digital outputs signals to downstream systems and devices (e.g., peripheral devices 130). System 100 may be embodied in circuitry utilized in an embedded system (e.g., an integrated circuit (IC), system-on-chip (SoC)), such as MCU 105. Elements of system 100 include dedicated, fixed-purpose hardware components capable of performing sampling and conversion operations as well as metastability detection operations, such as methods 300 and 301 of FIGS. 3A and 3B, respectively.

Processing cores 110 are representative of one or more processing units, cores, devices, or systems capable of executing program instructions from a memory device (e.g., memory 115) and controlling operations of ADC 120 based on executing the program instructions. Examples of processing cores 110 may include general processing units, central processing units (CPUs), digital signal processors (DSPs), field-programmable logic arrays (FPGAs), application-specific integrated circuits (ASICs), and the like, including combinations and variations thereof.

Memory 115 is representative of one or more non-transitory, computer-readable storage media capable of storing data and program instructions for execution by processing cores 110. Examples of memory 115 include volatile memory devices, such as random access memory (RAM), tightly coupled memory (TCM), and the like. Examples of memory 115 also include non-volatile memory devices, such as flash memory. In some examples, MCU 105 may include multiple memory devices integrated together or separately.

ADC 120 is representative of analog-to-digital conversion circuitry, such as a successive approximation register (SAR) ADC. ADC 120 is configured to receive analog input signals (e.g., from sensor peripheral devices 135), convert the analog input signals to respective digital output signals, and output the digital output signals for use by one or more devices, including internal devices (e.g., processing cores 110, peripheral devices 130) and external devices (e.g., sensor peripheral devices 135).

I/O devices 125 and 126 are representative of interface devices including pins, ports, pads, or nodes configured to couple to and interface with sensor peripheral devices 135. I/O devices 125 and 126 may provide both internal and external connections to components of MCU 105, such as ADC 120, such that, when sensor peripheral devices 135 are coupled to MCU 105 at I/O device 125 or I/O device 126, sensor peripheral devices 135 can provide analog input signals to ADC 120 via I/O device 125 and/or I/O device 126. It follows that sensor peripheral devices 135 may be off-chip relative to components of MCU 105. In some examples, sensor peripheral devices 135 are onboard MCU 105. Peripheral devices 130 are representative of analog circuits, digital circuits, or processing devices capable of using digital output signals provided by ADC 120 to enable their respective functionality. Similarly, sensor peripheral devices 135 are representative of analog circuits, digital circuits, or processing devices, such as sensors, capable of obtaining analog signals and driving analog signals as inputs to ADC 120 via I/O devices 125 and 126.

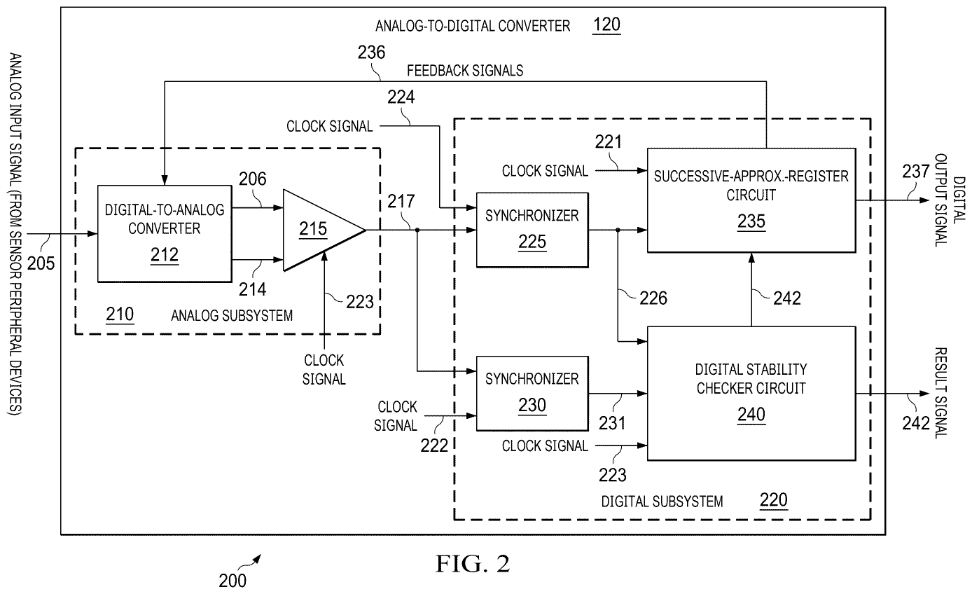

An example block diagram 200 illustrating components of ADC 120 is shown in FIG. 2. In block diagram 200, ADC 120 includes analog subsystem 210 and digital subsystem 220. Analog subsystem 210 includes digital-to-analog converter (DAC) 212 and comparator 215, and digital subsystem 220 includes synchronizer 225, synchronizer 230, successive approximation register (SAR) circuit 235, and digital stability checker circuit 240.

DAC 212 is representative of digital-to-analog conversion circuitry capable of converting analog inputs to digital outputs for use by other components of ADC 120. In some examples, DAC 212 is representative of a capacitive digital-to-analog converter.

DAC 212 is coupled to receive analog input signal 205 from one or more sensor peripheral devices (e.g., sensor peripheral devices 135) and feedback signals 236 from SAR circuit 235. Analog input signal 205 includes a set of analog values to be converted by ADC 120 during an analog-to-digital conversion period. Feedback signals 236 are representative of sets of digital bits generated by SAR circuit 235 and used to determine digital output signal 237. More particularly, each feedback signal generated by SAR circuit 235 may correspond to an analog value (e.g., analog value 206) of analog input signal 205 and may be used during an analog-to-digital conversion period to generate a digital bit of digital output signal 237 for the analog value. Based on a given feedback signal, DAC 212 generates weighted voltage 214 (e.g., an analog voltage representation of the digital bits of a feedback signal) as a function of the feedback signal and a respective analog input value of analog input signal 205 (e.g., analog value 206). This may entail converting the feedback signal to an analog voltage value. DAC 212 outputs weighted voltage 214 to comparator 215.

Comparator 215 is included to perform bit decision-making with respect to the analog-to-digital conversion period. Comparator 215 is coupled to receive weighted voltage 214 from DAC 212, analog value 206 (e.g., a reference value), and clock signal 223 from a clock generation circuit. In operation, comparator 215 performs a comparison between a weighted voltage 214 and analog value 206 to generate decision signal 217. Decision signal 217 includes a binary value (e.g., 0, 1) corresponding to a result of the comparison performed by comparator 215. For example, decision signal 217 includes a value of 1 based on weighted voltage 214 being higher than analog value 206, and decision signal 217 includes a value of 0 based on weighted voltage 214 being lower than analog value 206. The time at which comparator 215 generates and outputs decision signal 217 is based on clock signal 223.

Synchronizers 225 and 230 are included in ADC 120 to store values of decision signal 217 at different times. In particular, synchronizer 225 includes one or more flip-flop devices coupled to receive decision signal 217 and clock signal 224, while synchronizer 230 includes one or more flip-flop devices coupled to receive decision signal 217 and clock signal 222. Synchronizer 225 stores decision value 226 associated with decision signal 217 at a time based on clock signal 224. Synchronizer 230 stores decision value 231 associated with decision signal 217 at a time based on clock signal 222.

Clock signal 222 includes a clock signal with a sequence of clock cycles delayed relative to clock cycles of clock signal 224. Accordingly, the time at which synchronizer 230 stores decision value 231 occurs after the time at which synchronizer 225 stores decision value 226. Given the delay in capturing values of decision signal 217, decision value 226 and decision value 231 may include different values based on the digital stability of ADC 120. In this way, synchronizer 230 provides redundancy in ADC 120 to determine digital stability by capturing a second value of decision signal 217 at a second time. In some examples, synchronizers 225 and 230 are both single-stage synchronizer devices, and as such, can capture respective values to determine digital stability in a single clock cycle.

Synchronizer 225 is coupled to provide decision value 226 to SAR circuit 235 and to digital stability checker circuit 240. Synchronizer 230 is coupled to provide decision value 231 to digital stability checker circuit 240.

SAR circuit 235 is representative of sample and conversion circuitry capable of performing algorithms during the analog-to-digital conversion period to generate digital output signal 237 for use by downstream systems (e.g., peripheral devices 130). By way of example, ADC 120 is a 12-bit ADC. In such an example, SAR circuit 235 determines 12 bits over 12 conversion cycles to produce digital output signal 237.

During each conversion cycle, SAR circuit 235 receives a value (e.g., decision value 226) from comparator 215 via synchronizer 225 and produces a digital bit of digital output signal 237 based on feedback signals 236 and decision value 226. More specifically, based on decision value 226 including a 0 (e.g., indicative of given feedback signal being lower than a corresponding analog value of analog input signal 205), SAR circuit 235 generates a digital bit corresponding to a digital bit of feedback signal 237. Based on decision value 226 including a 1 (e.g., indicative of a given feedback signal being higher than a corresponding analog value), SAR circuit 235 generates a digital bit of feedback signal 237 having an opposite value of a corresponding bit of the given feedback signal. Then, SAR circuit 235 generates another feedback signal to determine a subsequent bit of digital output signal 237 associated with a subsequent analog value of analog input signal 205. The timing with which SAR circuit 235 operates is based on clock signal 221.

Also, during each conversion cycle, digital stability checker circuit 240 receives decision values 226 and 231 from the synchronizers and generates result signal 242 based on decision values 226 and 231. Digital stability checker circuit 240 is representative of one or more components capable of comparing decision values 226 and 231 to determine a state of digital stability within ADC 120. A state of metastability occurs when comparator 215 has not resolved a value of decision signal 217 to a binary value (e.g., 0, 1) within an amount of time (e.g., a time based on a delay between clock signal 223 and clock signal 224). As a result, decision value 226 may be either a 0 or 1 with no reliable relationship to the eventual state of decision signal 217 or, by extension, to decision value 231 produced later in the same cycle. A state of digital stability occurs when decision values 226 and 231 include the same values.

By way of example, digital stability checker circuit 240 produces result signal 242 indicative of the state of metastability based on decision values 226 and 231 having different values. In particular, synchronizer 225 stores decision value 226 at a first time during which decision signal 217 includes a value between 0 and 1 (i.e., has not resolved to a 0 or 1) (e.g., an unstable value). Then, synchronizer 230 stores decision value 231 at a second, later time during which decision signal 217 includes a 0 or 1 (e.g., a stable value). The differing values of decision values 226 and 231 indicate that comparator 215 is metastable for at least a duration during operation. Based on digital stability checker circuit 240 outputting result signal 242 indicative of the state of metastability, operations of SAR circuit 235 may be controlled to avoid producing erroneous digital bits of digital output signal 237 (e.g., an output including sparkle code).

Based on result signal 242 indicating digital stability (e.g., decision values 226 and 231 are the same), SAR circuit 235 operates as described above to produce digital output signal 237. However, based on result signal 242 indicating metastability within ADC 120 (e.g., decision values 226 and 231 are different), SAR circuit 235 may terminate the conversion period early (e.g., approximate digital output signal 237 by using previously captured bits without using metastable bit(s)) or generate digital output signal 237 based on decision value 231. An example of operations performed by components of ADC 120 to detect metastability is shown and described in methods 300 and 301 of FIGS. 3A and 3B below.

Referring now to FIGS. 3A and 3B, methods 300 and 301 may be implemented in logic in the context of hardware elements of an analog-to-digital converter (e.g., ADC 120). The logic, when performed by ADC 120, directs components thereof to operate as follows, referring to elements of system 200 of FIG. 2. Particularly, method 300 relates to operations performed by analog subsystem 210 of ADC 120, while method 301 relates to operations performed by digital subsystem 220 of ADC 120.

To begin method 300, in operation 305, DAC 212 of ADC 120 receives analog input signal 205 from a device (e.g., a sensor peripheral device) to be converted to digital output signal 237. To begin conversion of an analog input signal, DAC 212 receives an analog value of the analog input signal and receives feedback signals 236 from SAR circuit 235. During the first conversion cycle, feedback signals 236 may include an initial value (e.g., a value including a most-significant bit set to 1 and all other bits set to 0) to initialize the conversion period. Based on feedback signals 236, DAC 212 generates weighted voltage 214 as a function of feedback signals 236 based on converting feedback signals 236 to an analog voltage. For a given bit (e.g., analog value 206), DAC 212 outputs weighted voltage 214 and the analog value 206 to comparator 215.

Comparator 215 compares weighted voltage 214 to analog value 206 to determine whether weighted voltage 214 is higher or lower than analog value 206. Upon comparing the values, in operation 310, comparator 215 generates a decision signal 217 having a binary value (e.g., 0, 1) indicative of the comparison result. For example, based on weighted voltage 214 being higher than analog value 206, decision signal 217 includes a value of 1, and based on weighted voltage 214 being lower than analog value 206, decision signal 217 includes a value of 0. In operation 315, comparator 215 outputs decision signal 217 to synchronizers 225 and 230 at a time based on clock signal 223.

Next, components of digital subsystem 220 receive decision signal 217 to begin method 301 of FIG. 3B. In operation 320, synchronizer 225 receives decision signal 217 and stores a value (e.g., decision value 226) of the decision signal at a time based on clock signal 224, and synchronizer 230 receives decision signal 217 and stores a value (e.g., decision value 231) of the decision signal at a time based on clock signal 222. In various examples, synchronizer 225 stores decision value 226 at a time after decision signal 217 is output by comparator 215 but before synchronizer 230 stores decision value 217 based on respective clock signals. In some such examples, decision value 226 is different from decision value 231 based on the delay in capturing respective values of decision signal 216. For example, the value of decision signal 217 may include a value between 0 and 1 (e.g., has not resolved yet, e.g., is metastable) if comparator 215 is unable to resolve the comparison within a duration based on clock signal 223. However, the value of decision signal 217 may include a 0 or 1 by the time synchronizer 230 captures decision value 231.

Synchronizer 225 outputs the decision signal having decision value 226 to SAR circuit 235 and to digital stability checker circuit 240. Synchronizer 230 outputs the decision signal having decision value 231 to digital stability checker circuit 240.

In operation 325, SAR circuit 235 identifies decision value 226 and generates digital output signal 237 and feedback signals 236 based on decision value 226. Generating digital output signal 237 may entail performing one or more algorithms to determine a digital bit value of digital output signal 237 based on decision value 226. More specifically, SAR circuit 235 determines a digital bit value of digital output signal 237 based on a previously output feedback signal and based on decision value 226. Then, SAR circuit 235 generates another feedback signal having a different combination of bits than the previously provided feedback signal. SAR circuit 235 outputs feedback signal 236 to DAC 212 for further use during the conversion period (if not completed), and SAR circuit 235 outputs digital output signals 237 for use by downstream subsystems upon completion of the conversion period.

During the conversion period, in operation 330, digital stability checker circuit 240 compares decision values 226 and 231 captured by synchronizers 225 and 230, respectively, to determine a state of metastability of decision signal 217. Based on identifying that decision values 226 and 231 are the same, digital stability checker circuit 240 determines that decision signal 217 is a metastable signal, and as such, the state of ADC 120 corresponds to a state of digital stability. Based on identifying that decision values 226 and 231 are different, digital stability checker circuit 240 determines that decision signal 217 includes a metastable value, and as such, the state of ADC 120 corresponds to a state of metastability, at least for a duration.

In operation 335, digital stability checker circuit 240 generates result signal 242 based on the state of metastability. Result signal 242 may include a first value indicative of the digital stability state or a second value indicative of metastability. In operation 340, digital stability checker circuit 240 outputs result signal 242. In some examples, digital stability checker circuit 240 provides result signal 242 to one or more processing cores (e.g., processing cores 110), to SAR circuit 235, and/or to one or more downstream subsystems.

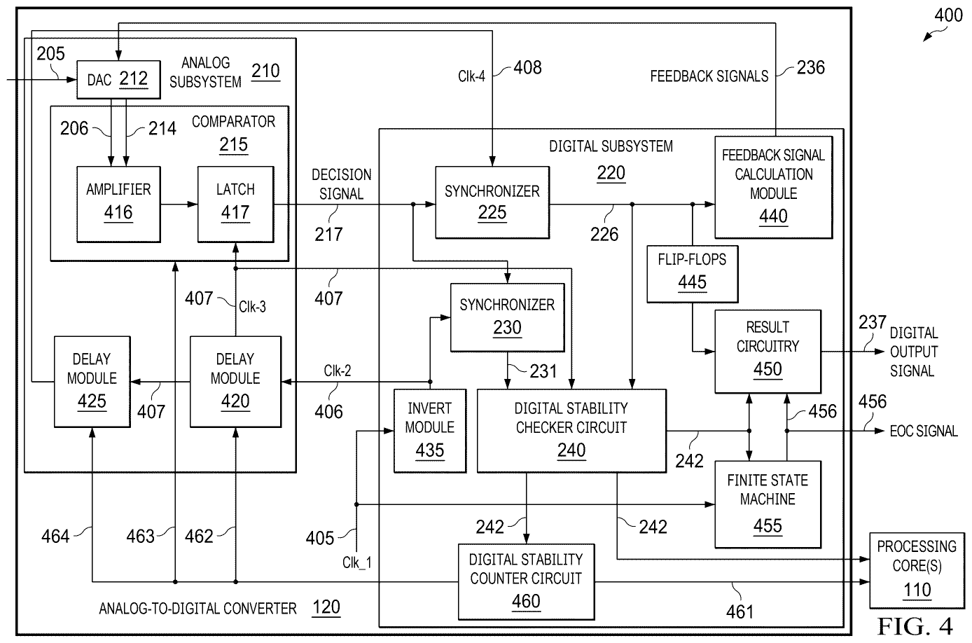

FIG. 4 illustrates an example block diagram 400 that shows additional components of ADC 120 in an implementation. Block diagram 400 includes processing cores 110 and ADC 120. In block diagram 400, ADC 120 includes various components categorically arranged into analog subsystem 210 and digital subsystem 220.

Analog subsystem 210 includes circuitry of ADC 120 configured to perform analog logic operations with respect to analog-to-digital conversion. Digital subsystem 220 includes circuitry of ADC 120 configured to perform digital logic operations with respect to analog-to-digital conversion. The analog logic operations refer to operations performed by components of ADC 120 on analog signals, while the digital logic operations refer to operations performed by components of ADC 120 on digital signals. Some components may perform operations on both types of signals.

As shown in block diagram 400, analog subsystem 410 includes digital-to-analog converter (DAC) 212, comparator 215, delay module 420, and delay module 425. Digital subsystem 220 includes synchronizer 225, synchronizer 230, digital stability checker circuit 240, invert module 435, feedback signal calculation module 440, flip-flops 445, result circuitry 450, finite state machine (FSM) 455, and digital stability counter circuit 460.

DAC 212 includes an array of electrical components (e.g., resistors, capacitors) having an input coupled to receive analog input signal 205, an input coupled to receive feedback signals 236 from feedback signal calculation module 440, and an output coupled to comparator 215. For each feedback signal received by DAC 212, DAC 212 generates a corresponding weighted voltage (e.g., an analog representation of the digital bits of the feedback signal) and outputs the weighted voltage to comparator 215. DAC 212 also outputs an analog value of analog input signal 205 to comparator 215. In an example shown in block diagram 400, DAC 212 receives feedback signals 236 and generates weighted voltage 214 based on feedback signals 236. DAC 212 outputs weighted voltage and a corresponding analog value 206 of analog input signal 205 to comparator 215.

Comparator 215 includes amplifier 416 and latch 417 to perform comparison operations with respect to analog values and weighted voltages and generate decision signal 217. By way of example, amplifier 416 receives weighted voltage 214 and analog value 206 as inputs, amplifies the inputs with respect to voltage, and outputs an amplified weighted voltage and analog value to latch 417. Latch 417 receives amplified versions of weighted voltage 214 and analog value 206 and stores a binary value (e.g., 0, 1) based on a comparison of the values at a time based on clock signal 407 (e.g., at a rising edge of a clock cycle of clock signal 407). More particularly, latch 417 may store a value of 1 based on weighted voltage 214 being higher than analog value 206 and a value of 0 based on weighted voltage 214 being lower than analog value 206. Latch 417 then outputs decision signal 217, which includes an indication of the result of the comparison based on clock signal 407 (e.g., at a rising edge of a clock cycle of clock signal 407).

Synchronizers 225 and 230 are coupled to receive decision signal 217 from latch 417. Synchronizers 225 and 230 are further coupled to receive clock signals 408 and 406, respectively. Synchronizer 225 stores a value (e.g., decision value 226) (e.g., 0, 1) of decision signal 217 at a time based on clock signal 408, while synchronizer 230 stores a value (e.g., decision value 231) (e.g., 0, 1) of decision signal 217 at another time based on clock signal 406. Synchronizer 225 outputs decision value 226 to feedback signal calculation module 440, to flip-flops 445, and to digital stability checker circuit 240. Synchronizer 230 outputs decision 231 to digital stability checker circuit 240.

Feedback signal calculation module 440 is representative of one or more elements of successive approximation register (SAR) circuitry (e.g., SAR circuit 235) that is capable of generating feedback signals 236 based on decision value 226. In particular, feedback signal calculation module 440 identifies decision value 226 and determines a new combination of digital bits (relative to a previously output combination of bits) based on decision value 226. By way of example, a first feedback signal includes a first sequence of bits including a one (1) for a first bit (e.g., a most-significant bit) and zeros (0) for the remainder of the bits. Based on decision value 226, feedback signal calculation module 440 generates a second feedback signal that includes a second sequence of bits including a one (1) for a second bit and zeros (0) for the remainder of the bits. Each combination of bits may be used to determine a digital bit of digital output signal 237 corresponding to an analog value of analog input signal 205. Feedback signal calculation module 440 outputs the second feedback signal to DAC 212 to repeat the conversion processes described above.

Flip-flops 445 and result circuitry 450 are also included in the SAR circuitry. Flip-flops 445 store decision value 226 and output decision value 226 to result circuitry 450. Result circuitry 450 generates digital output signal 237 based on decision value 226 and feedback signals 236. For example, for a first digital bit, upon determining decision value 226 is a value indicative of weighted voltage 214 being higher than analog value 206 (e.g., 1), result circuitry 450 determines a value opposite the value of the first feedback signal output by feedback signal calculation module 440. Similarly, for the first digital bit, upon determining decision value 226 is a value indicative of weighted voltage 214 being lower than analog value 206 (e.g., 0), result circuitry 450 determines the first digital bit based on a corresponding value of the first feedback signal. After determining all of the digital bits of digital output signal 237, result circuitry 450 outputs digital output signal 237.

FSM 455 is also included in the SAR circuitry to control operations of result circuitry 450. In particular, FSM 455 operates based on clock signal 405 to determine a start and end of each conversion cycle of an analog-to-digital conversion period. Based on determining the end of the last conversion cycle, FSM 455 outputs end of conversion (EOC) signal 456 (e.g., a signal indicative of the last conversion cycle in a conversion period) to result circuitry 450. Upon receiving EOC signal 456, result circuitry 450 generates the last bit for digital output signal 237 and outputs digital output signal 237. FSM 455 also outputs EOC signal 456 to other components (e.g., peripheral devices 130) to provide an indication of the end of the conversion period.

During the conversion period, digital stability checker circuit 240 compares decision values 226 and 231 captured by synchronizers 225 and 230, respectively, to determine a state of metastability of decision signal 217. In various examples, the time at which synchronizer 225 stores decision value 226 occurs before the time at which synchronizer 230 stores decision value 231 based on a delay between clock signals 406 and 408. In some examples, decision value 226 may be different than decision value 231. Decision value 226 may include a value between 0 and 1 (e.g., a metastable value) based on latch 417 failing to resolve the result of the comparison between weighted voltage 214 and analog value 206 within an amount of time based on clock signals 407 and 408. If latch 417 resolves the result of the comparison within an amount of time based on clock signals 407 and 409, synchronizer 230 stores decision value 231 that includes a 0 or 1, and thus, decision values 226 and 231 have different values.

Based on identifying that decision values 226 and 231 are the same, digital stability checker circuit 240 determines that decision signal 217 is a metastable signal, and as such, the state of ADC 120 corresponds to a state of digital stability. However, based on identifying that decision values 226 and 231 are different, digital stability checker circuit 240 determines that decision signal 217 includes a metastable value, and as such, the state of ADC 120 corresponds to a state of digital instability. Digital stability checker circuit 240 generates result signal 242 indicative of the state of metastability and outputs result signal 242 to result circuitry 450, FSM 455, processing cores 110, and digital stability control circuit 460.

Upon receiving result signal 242 indicative of digital instability (metastability), FSM 455 controls operations of result circuitry 450. For example, FSM 455 may provide EOC signal 456 to result circuitry 450 prior to the end of the conversion period to terminate operations of result circuitry 450 early. In such examples, result circuitry 450 may output (an approximation of) digital output signal 237 based on calculating a final result for the digital signal using bits captured prior to the detection of metastability and using zeros (0) for lower order bits (e.g., least significant bits). By way of another example, FSM 455 directs result circuitry 450 to use decision value 231, as opposed to decision value 226, to generate a particular digital bit of digital output signal 237. In this way, if decision value 226 includes a metastable value but decision value 231 includes a stable value, result circuitry 450 can generate digital output signal 237 with one or more stable values to avoid producing noisy or erroneous digital bits.

Digital stability counter circuit 460 is included in ADC 120 to maintain a counter value and control parameters of components of analog subsystem 210. In particular, digital stability counter circuit 460 includes a counter and increments the counter value of the counter based on result signal 242 indicating metastability within ADC 120. Upon the counter value exceeding a threshold counter value, digital stability counter circuit 460 outputs interrupt signal 461 to processing cores 110, delay signal 462 to delay module 420, trim signal 463 to comparator 215, and delay signal 464 to delay module 425.

Interrupt signal 461 indicates that the counter value of digital stability counter circuit 460 exceeds the threshold counter value. In response to receiving interrupt signal 461, processing cores 110 may be configured to use decision value 231 to determine and replace a digital bit of digital output signal 237. By way of yet another example, processing cores 110 might not use digital output signal 237 based on a detection of metastability.

Delay signal 462, trim signal 463, and delay signal 464 indicate parameters that components of analog subsystem 210 can implement to update operations or timing thereof. More specifically, trim signal 463 may include a trim parameter (e.g., input reference voltage) for comparator 215 to implement to configure operational settings for current or upcoming comparison operations. Delay signal 462 may include a delay parameter indicating an amount of delay for delay module 420 to add to or remove from clock signal 407. Similarly, delay signal 464 may include a delay parameter indicating an amount of delay for delay module 425 to add to or remove from clock signal 408. Clock signals 407 and 408 include two of the clock signals used by ADC 120 to control the timing with which components of ADC 120 operate. It may be appreciated that processing cores 110

Referring more specifically to the clock signals shown in block diagram 400, the components of ADC 120 operate as discussed above based on clock signal 405 and variations thereof. Clock signal 405 represents a first clock signal provided to invert module 435 and FSM 455 of digital subsystem 220. Clock signal 405 includes a first sequence of clock cycles used to coordinate operations of components. Invert module 435 inverts the first sequence of clock cycles to generate clock signal 406. Accordingly, clock signal 406 includes a second sequence of clock cycles inverted relative to the first sequence of clock cycles. In some examples, invert module 435 inverts the first sequence of clock cycles such that the second sequence of clock cycles are 180 degrees out-of-phase relative to the first sequence of clock cycles. Invert module 435 provides clock signal 406 to synchronizer 230 and to delay module 420.

Delay module 420 first inverts (e.g., by 180 degrees) the second sequence of clock cycles to produce a third sequence of clock cycles in-phase relative to the first sequence of clock cycles of clock signal 405. Then, delay module 420 delays the third sequence of clock cycles by an offset amount to generate clock signal 407 having the third sequence of clock cycles that transition between logical states (e.g., 0 to 1, 1 to 0) at a later time relative to the clock cycles of clock signals 405 and 406. Delay module 420 outputs clock signal 407 to latch 417 of comparator 215 and to delay module 425.

Delay module 425 further delays the third sequence of clock cycles to produce a fourth clock signal, clock signal 408, that includes a fourth sequence of clock signals. Thus, the fourth sequence of clock cycles transition between logical states later than the clock cycles of clock signals 405, 406, and 407. Delay module 425 outputs clock signal 408 to synchronizer 225. It follows that comparator 215 operates (e.g., compares and outputs decision signal 217) before synchronizers 225 and 230 based on clock signal 407, and synchronizer 225 operates (e.g., stores decision value 226) before synchronizer 230 operates (e.g., stores decision value 231).

The amount of delay between the operations of each components is based on the offset amount added to respective clock cycles. Accordingly, based on digital stability counter circuit 460 outputting delay signal 462 and delay signal 464, digital stability counter circuit 460 can delay the operations of synchronizer 225 relative to the operations of comparator 215 such that more time may pass before synchronizer 225 captures decision value 217, which in turn increases the amount of time that comparator 215 has to resolve the value for decision signal 217. In this way, digital stability counter circuit 460 may reduce the likelihood of metastability in ADC 120.

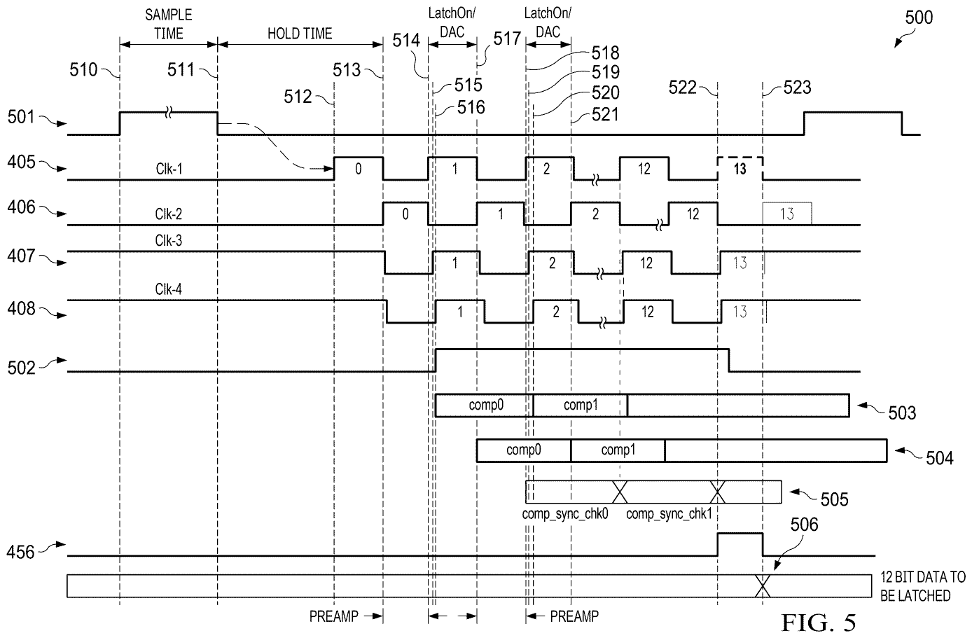

Visual representations of the clock signals are illustrated in timing diagram 500 of FIG. 5. Timing diagram 500 shows example logical state values output by components of a system (e.g., ADC 120) at different times during sampling and conversion operations. The state values demonstrated by timing diagram 500 are illustrated as logical high signals (“1” or “on”) and logical low signals (“0” or “off”) depending on states of the corresponding signals.

Sampling enable signal 501 is representative of a signal that controls sampling operations of ADC 120. When in a logical high state, sampling enable signal 501 enables ADC 120 to perform sampling operations on analog input signal 205, and when in a logical low state, sampling enable signal 501 enables ADC 120 to hold the sampled voltage value by providing a corresponding analog signal for conversion that has the sampled voltage value. In various examples, processing cores 110 provides sampling enable signal 501 to ADC 120, and ADC 120 performs the sampling operations when sampling enable signal 501 indicates a logical high state.

Clock signal 405 is a first clock signal provided to ADC 120. Clock signal 405 includes a first sequence of clock cycles that transition between low and high logical states beginning at time 512 for a number of times based on the conversion period of ADC 120.

Clock signals 406, 407, and 408 are clock signals generated based on clock signal 405. Clock signal 406 includes a second sequence of clock cycles inverted (e.g., by 180 degrees) relative to the first sequence of clock cycles. For example, the second sequence of clock cycles transition from low logical states to high logical states when the first sequence of clock cycles of clock signal 405 transition from high logical states to low logical states. Clock signal 407 includes a third sequence of clock cycles in-phase relative to the first sequence of clock cycles but offset by a delay amount. As such, the third sequence of clock cycles transition between logical states at a later time relative to the clock cycles of clock signals 405 and 406. Clock signal 408 includes a fourth sequence of clock signals in-phase relative to the first and third sets of clock cycles but offset by a further delay amount. Thus, the fourth sequence of clock cycles transition between logical states later than the clock cycles of clock signals 405, 406, and 407.

Metastability check enable signal 502 is representative of a signal that controls operations of digital stability checker circuit 240 during the conversion period. More specifically, when metastability check enable signal 502 is in the high logical state, digital stability checker circuit 240 is enabled to perform comparisons between values provided to digital stability checker circuit 240 by synchronizers 225 and 230 and output result signal 242 based on the comparisons. Metastability check enable signal 502 may transition to the high logical state based on clock signal 408 and may remain in the high logical state until the completion of the conversion period.

Decision signal value capture phases 503 and 504 refer to sub-cycles during the conversion period during which synchronizers 225 and 230 store decision values 226 and 231, respectively. Decision signal value capture phase 503 is based on clock signal 408, while decision signal value capture phase 504 is based on clock signal 406. More particularly, the capture operation by synchronizer 225 during decision signal value capture phase 503 occurs based on a transition of clock signal 408 from a logical low state to a logical high state (e.g., at time 516). The capture operation by synchronizer 230 during decision signal value capture phase 504 occurs based on a transition of clock signal 406 from a logical low state to a logical high state (e.g., at time 517).

Comparison phase 505 refers to sub-cycles during the conversion period during which digital stability checker circuit 240 compares decision values 226 and 231 during decision signal value capture phases 503 and 504. Comparison phase 505 is based on clock signal 407. More particularly, the comparison operation performed by digital stability checker circuit 240 occurs based on a transition of clock signal 407 from a logical high state to a logical low state (e.g., at time 519) following decision signal value capture phases 503 and 504.

End of conversion signal 456 is representative of a signal output by FSM 455 at the end of the conversion cycle as an indication thereof. In an example where ADC 120 is representative of a 12-bit ADC, FSM 455 outputs end of conversion signal 456 at the transition of the last clock cycle (e.g., the 14^{th} clock cycle) of clock signal 405. When end of conversion signal 456 transitions from the logical high state to the logical low state (e.g., at time 523), digital output signal 506 (e.g., digital output signal 237) can be latched by ADC 120 and output to downstream devices and systems.

Referring more particularly to specific points in time with respect to timing diagram 500, at time 510, sampling enable signal 501 transitions from the logical low state to the logical high state to begin the sampling period. From time 510 and until time 511, ADC 120 samples analog input signal 205 prior to beginning the conversion period. At time 511, sampling enable signal 501 transitions from the logical high state to the logical low state ending the sampling period. From time 511 to time 512 while the clock signals remain in the logical low states, DAC 212 of ADC 120 holds sampled values of analog input signal 205. In this hold state beginning at time 511, DAC 212 generates weighted voltages based on feedback signals 236 to be compared with analog input signal 205.

At time 512, clock signal 405 transitions from the logical low state to the logical high state and continues to transition between each state with a given duty cycle. At time 513, clock signal 405 transitions from the logical high state to the logical low state and clock signal 406 transitions from the logical low state to the logical high state and continues to transition between each state with a given duty cycle such that clock signals 405 and 406 transition between opposite states relative to one another until the end of the conversion period.

Additionally, at time 513, amplifier 416 of comparator 215 obtains a weighted voltage (e.g., weighted voltage 214) corresponding to the first bit (e.g., analog value 206) for conversion and amplifies the voltage to a higher voltage for use by latch 417 of comparator 215. At time 514, clock signal 405 transitions from the logical low state to the logical high state, and consequently, clock signal 406 transitions from the logical high state to the logical low state. At this time, latch 417 generates decision signal 217 based on the weighted voltage and the corresponding analog value.

At time 515, clock signal 407 transitions from the logical low state to the logical high state. When clock signal 407 transitions to the logical high state, latch 417 outputs decision signal 217 to synchronizers 225 and 230. Shortly thereafter, at time 516, clock signal 408 transitions from the logical low state to the logical high state. When clock signal 408 transitions to the logical high state, metastability check enable signal 502 also transitions to the logical high state to enable a metastability detection operation and begin decision signal value capture phase 503. During decision signal value capture phase 503, synchronizer 225 obtains decision signal 217 from latch 417 and stores a first value associated with decision signal 217 at time 516 (e.g., decision value 226) (denoted by “comp0” in decision signal value capture phase 503 in timing diagram 500).

Between time 516 and 517, feedback signal calculation module 440 obtains decision value 226 stored by synchronizer 225, generates feedback signals 236 based on decision value 226, and outputs feedback signals 236 to DAC 212.

At time 517, clock signal 405 transitions from the logical high state to the logical low state, and clock signal 406 transitions from the logical low state to the logical high state. As clock signal 406 transitions to the logical high state, and based on metastability check enable signal 502 being in the logical high state, decision signal value capture phase 504 is enabled during which synchronizer 230 obtains decision signal 217 from latch 417 and stores a second value associated with decision signal 217 at time 517 (e.g., decision value 231) (denoted by “comp0” in decision signal value capture phase 504 timing diagram 500).

In various examples, the duration between times 515 and 516 during which comparator 215 generates and outputs decision signal 217 and during which synchronizer 225 captures decision value 226 is shorter than the duration between times 515 and 517 during which comparator 215 generates and outputs decision signal 217 and during which synchronizer 230 captures decision value 231. In some such examples, decision value 226 is different than decision value 231 as latch 417 might not have resolved the value of decision signal 217 by time 516 when synchronizer 225 stores decision value 226. In such examples, decision signal 217 is referred to as being metastable. However, based on the longer duration from time 515 until time 517, by the time synchronizer 230 stores decision value 231 at time 517, latch 417 may have resolved the value of decision signal 217, and thus, decision signal 217 might not be in a metastable state by time 517.

Also, at time 517, amplifier 416 may obtain a weighted voltage corresponding to a second bit for conversion (e.g., bit 1) based on feedback signals 236. Amplifier 416 amplifies the voltage to a higher voltage signal for use by latch 417 to repeat the process above. At time 418, clock signal 405 transitions from the logical low state to the logical high state, and clock signal 406 transitions from the logical high state to the logical low state. At this time, latch 417 receives the weighted voltage and a corresponding analog value and generates decision signal 217 having a value based on the weighted voltage and the analog value.

At time 519, clock signal 407 transitions from the logical low state to the logical high state, and as a result, latch 417 outputs decision signal 217 to synchronizers 225 and 230. Shortly thereafter, at time 520, clock signal 408 transitions from the logical low state to the logical high state. During these times, metastability check enable signal 502 remains in the logical high state, so a second capture phase of decision signal value capture phase 503 begins. During the second capture phase of decision signal value capture phase 503, synchronizer 225 obtains decision signal 217 from latch 417 and stores a value associated with decision signal 217 at time 520 (denoted by “comp1” in decision signal value capture phase 503 in timing diagram 500).

Also at time 519, comparison phase 505 occurs during which digital stability checker circuit 240 obtains decision values 226 and 231 and performs a comparison between the two values. Digital stability checker circuit 240 generates result signal 242 including an indication of a state of metastability of decision signal 217. If the two values are the same, digital stability checker circuit 240 outputs an indication of digital stability, and if the two values are different, digital stability checker circuit 240 outputs an indication of digital instability, or metastability. In various examples, based on the state of metastability, the conversion period may continue, or it may be terminated.

Following an example where the conversion period continues, ADC 120 may repeat the above operations using the various clock signals and based on the rising and falling edges thereof. For example, in continuing the conversion period, at time 521, clock signal 405 transitions from the logical high state to the logical low state, and clock signal 406 transitions from the logical low state to the logical high state. As clock signal 406 transitions to the logical high state and, based on metastability check enable signal 502 being in the logical high state, decision signal value capture phase 504 may be enabled during which synchronizer 230 obtains decision signal 217 from latch 417 and stores a value associated with decision signal 217 at time 521 (denoted by “comp1” in decision signal value capture phase 504 timing diagram 500). Again, a second iteration of comparison phase 505 may occur to determine the state of metastability after the second bit of the digital output signal is generated by ADC 120. The conversion period may continue or terminate following the second iteration of comparison phase 505 based on the state of metastability determined by digital stability checker circuit 240.

Following the above example, ADC 120 may continue the conversion period until a digital output signal is generated based on analog input signal 205 at time 522. At time 522, end of conversion signal 456 may be output by FSM 455 indicating the end of the conversion period. When end of conversion signal 456 transitions from the logical high state back to the logical low state at time 523, ADC 120 outputs digital output signal 506. The sampling and conversion period may begin again using different analog input data following the same or a similar process as shown in timing diagram 500.

In some examples, the conversion period may terminate early based on the state of metastability. For example, following the first, second, or another phase of comparison phase 505, based on digital stability checker circuit 240 determining that decision signal 217 is in the metastable state, FSM 455 may control result circuitry 450 to end the conversion period by providing end of conversion signal 456 to result circuitry 450 at a time before time 522. In some such examples, result circuitry 450 generates a digital output signal using fewer than 12 bits of data. In some such examples, result circuitry 450 may generate the digital output signal using the values stored by synchronizer 225 and/or synchronizer 230, or a combination or variation thereof.

While some examples provided herein are described in the context of a digital signal processing system, sampling and conversion circuitry, power circuitry, clock generation circuitry, metastability detection circuitry, counter circuitry, logic circuitry, an embedded system or system-on-chip, sub-circuit, system, subsystem, component, device, architecture, or environment, it should be understood that the circuits, devices, logic elements, and other components, systems, and methods described herein are not limited to such embodiments and may apply to a variety of other processes, systems, applications, devices, and the like, such as other circuits, logic devices, transistors, and the like, in the context of sampling and conversion functionality, for example. Accordingly, aspects of the present invention may be embodied as other systems, methods, and other configurable systems.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The phrases “in some embodiments,” “according to some embodiments,” “in the embodiments shown,” “in other embodiments,” and the like generally mean the particular feature, structure, or characteristic following the phrase is included in at least one implementation of the present technology, and may be included in more than one implementation. In addition, such phrases do not necessarily refer to the same embodiments or different embodiments.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or sub combinations. Each of these processes or blocks may be implemented in a variety of different ways. Also, while processes or blocks are at times shown as being performed in series, these processes or blocks may instead be performed or implemented in parallel or may be performed at different times. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112 (f) will begin with the words “means for” but use of the term “for” in any other context is not intended to invoke treatment under 35 U.S.C. § 112 (f). Accordingly, the applicant reserves the right to pursue additional claims after filing this application to pursue such additional claim forms, in either this application or in a continuing application.

What is claimed is:

1. An analog-to-digital converter, comprising:
comparator circuitry configured to perform a comparison of an analog input signal to an analog feedback signal, and output a result of the comparison;
synchronization circuitry configured to sample the result of the comparison at different times, resulting in a first sampled value and a second sampled value;
digital output circuitry configured to generate a digital output signal based on the first sampled value, and output the digital output signal; and
stability checking circuitry configured to determine whether a metastability condition occurred with respect to the analog-to-digital converter based on the first sampled value and the second sampled value and output an indication of whether the metastability condition occurred.

2. The analog-to-digital converter of claim 1 wherein, to detect whether the metastability condition occurred, the stability checking circuitry is configured to perform a sample comparison between the first sampled value and the second sampled value, resulting in a sample comparison result.

3. The analog-to-digital converter of claim 2 wherein the stability checking circuitry is configured to determine that the metastability condition occurred when a result of the sample comparison indicates that the first sampled value differs from the second sampled value.

4. The analog-to-digital converter of claim 1 further comprising stability counter circuitry configured to:
increment a counter based on the stability checking circuitry outputting the indication specifying that the metastability condition occurred; and
in response to the counter exceeding a threshold, output one or more trim values associated with the comparator circuitry.

5. The analog-to-digital converter of claim 1 further comprising stability counter circuitry configured to:
increment a counter based on the stability checking circuitry outputting the indication specifying that the metastability condition occurred; and
in response to the counter exceeding a threshold, output an interrupt to one or more processing cores.

6. The analog-to-digital converter of claim 5, wherein the one or more processing cores are configured to adjust one or more trim values associated with the comparator circuitry based on the interrupt.

7. The analog-to-digital converter of claim 1, wherein the digital output circuitry is further configured to generate a digital feedback signal based on the first sampled value and output the digital feedback signal.

8. The analog-to-digital converter of claim 7 further comprising digital-to-analog converter circuitry configured to convert the digital feedback signal into the analog feedback signal.

9. A system comprising:
one or more processing cores; and
an analog-to-digital converter, comprising:
comparator circuitry configured to perform a comparison of an analog input signal to an analog feedback signal, and output a result of the comparison;
synchronization circuitry configured to sample the result of the comparison at different times, resulting in a first sampled value and a second sampled value;
digital output circuitry configured to generate a digital output signal based on the first sampled value, and output the digital output signal to the one or more processing cores; and
stability checking circuitry configured to detect a metastability condition of the comparator circuitry based on the first sampled value and the second sampled value and output an indication of whether the metastability condition occurred.

10. The system of claim 9 wherein, to detect the metastability condition, the stability checking circuitry is configured to perform a sample comparison between the first sampled value and the second sampled value, resulting in a sample comparison result.

11. The system of claim 10 wherein the stability checking circuitry is configured to determine that the metastability condition exists when a result of the sample comparison indicates that the first sampled value differs from the second sampled value.

12. The system of claim 9 further comprising stability counter circuitry configured to:
increment a counter each time the stability checking circuitry outputs the indication specifying that the metastability condition occurred; and
in response to the counter exceeding a threshold, output one or more trim values associated with the comparator circuitry.

13. The system of claim 9 further comprising stability counter circuitry configured to:
increment a counter each time the stability checking circuitry outputs the indication specifying that the metastability condition occurred; and
in response to the counter exceeding a threshold, output an interrupt to the one or more processing cores.

14. The system of claim 13 wherein the one or more processing cores are configured to adjust one or more trim values associated with the comparator circuitry based on the interrupt.

15. The system of claim 9 wherein the digital output circuitry is further configured to generate a digital feedback signal based on the first sampled value and output the digital feedback signal.

16. The system of claim 15 further comprising digital-to-analog converter circuitry configured to convert the digital feedback signal to the analog feedback signal.

17. A method for controlling metastability in an analog-to-digital converter (ADC) device, the method comprising, by circuitry of the ADC device:
performing a comparison of an analog input signal to an analog feedback signal, and outputting a result of the comparison;
sampling the result of the comparison at different times, resulting in a first sampled value and a second sampled value;
generating a digital output signal based on the first sampled value, and outputting the digital output signal; and
determining whether a metastability condition exists based on the first sampled value and the second sampled value and outputting an indication of whether the metastability condition exists.

18. The method of claim 17 further comprising, by the circuitry:
generating a digital feedback signal based on the first sampled value; and
converting the digital feedback signal to the analog feedback signal.

19. The method of claim 17 further comprising, by the circuitry:
incrementing a counter based on the metastability condition occurring; and
in response to the counter exceeding a threshold, adjusting one or more trim values associated with the circuitry.

20. The method of claim 17 further comprising, by the circuitry:
incrementing a counter based on the metastability condition occurring; and
in response to the counter exceeding a threshold, providing an interrupt to one or more processing cores with an indication of the metastability condition.
